(19) United States
(12) Patent Application Publication
(10) Pub. No.: US 2007/0020794 A1
(43) Pub. Date: Jan. 25, 2007

(54) Method of strengthening a microscale chamber formed over a sacrificial layer

(76) Inventor: Michael J. DeBar, Aliso Viejo, CA (US)

Correspondence Address: Mark G. Bocchetti;Patent Legal Staff, Eastman Kodak Company, 343 State Street, Rochester, NY, 14650-2201, US

(21) Appl. No.: 11/187,667

(22) Filed: Jul. 22, 2005

(51) Int. Cl. H01L 21/00; H01L 21/311; B41J 2/015; B41J 2/045

(52) U.S. Cl. 438/50; 347/68; 347/20; 438/694

(57) ABSTRACT

A method for forming an improved chamber for a micro-electromechanical device includes depositing a sacrificial layer on a substrate; depositing a masking layer on a surface of the sacrificial layer; removing at least one predetermined portion of the masking layer down to the sacrificial layer to form an etch pattern; isotropically etching the etch pattern into the sacrificial layer to a partial depth thereof and partially undercutting a remaining portion of the mask material; anisotropically etching the etch pattern into the sacrificial layer to the substrate to form a recessed pattern in the sacrificial layer with at least one anchor region on the substrate surrounding at least one plateau of sacrificial layer; removing the remaining masking layer; depositing a structural layer over the at least one plateau and filling the recessed pattern; providing an access port to the sacrificial layer; and removing the remaining sacrificial layer.

### FIELD OF THE INVENTION

The present invention relates to chambers in micro-electromechanical devices.

### BACKGROUND OF THE INVENTION

In many micro-electromechanical (MEMS) devices, a chamber is an essential component. Often, a structural layer deposited conformally over a patterned sacrificial layer forms this chamber. As will be appreciated by one skilled in the art, the planar nature of the surface micromachining processes traditionally used in MEMS manufacturing causes most standard processes to produce structures that are rectangular or trapezoidal in cross-section. If a chamber is formed over a rectangular or trapezoidal sacrificial mold, there will be a sharp corner, and therefore a stress concentration, in the chamber when the sacrificial layer is removed from beneath the chamber. As is well known to those skilled in the art, local stress is inversely proportional to the local radius of curvature, therefore a sharp corner has a small radius of curvature and a high local stress concentration. The intrinsic stress of the structural layer forming the chamber may cause it to fail mechanically at the point where the stress is concentrated, resulting in device failure due to the static forces present during device fabrication. Also, failure may occur during device use due to dynamic or external stresses, again causing failure at the point(s) where stress is most concentrated.

Elimination of these stress concentrations will decrease or eliminate the chance of mechanical failure of the chamber during fabrication, and will also prolong lifetime and robustness of the device. This is particularly important when the MEMS “system” is comprised of hundreds or thousands of devices, each of which must function for the system to be effectively utilized.

A micro-electromechanical device utilizing a chamber formed over a sacrificial layer is taught by Lutz (U.S. Pat. No. 6,521,965 B2). Lutz teaches the use of a sacrificial layer to form a gap between an electrode and a substrate in a capacitive pressure sensor.

Jarrold et al. (U.S. Pat. No. 6,561,627 B2) teach the use of a polyimide sacrificial layer to form a chamber in a thermally actuated inkjet print head. This device is disadvantaged however, since the polyimide sacrificial layer must be designed with sloped sidewalls to aid in the deposition of the top wall layer. This leads to a constraint on the horizontal resolution of the smallest feature, based on the sidewall angle and the polyimide layer thickness. For example, for a 10 um layer with a 60° sidewall angle, the horizontal extent of the polyimide sidewall surface is 5 um (10 um*cos(60°)). This is acceptable for many applications, but as miniaturization continues, one would be limited by this design constraint. For example, during inkjet printing with a native resolution of 600 dots per inch, the spacing between adjacent actuators must be no more than 42.3 um. In the above example, 25% of the available space would be used by the two sidewalls of the chamber.

Similarly, Silverbrook (U.S. Pat. No. 6,546,628 B2) uses a photosensitive polyimide or high temperature resist as a sacrificial layer in an inkjet actuator. Silverbrook teaches that there is both pattern distortion that must be compensated for, as well as a sloped sidewall that will increase the minimum dimension of the device.

Lebens (U.S. Pat. No. 6,644,786 B1) teaches the use of a non-photoimageable polyimide and an anisotropic etch to assure finer tolerances than those described above. Unfortunately, this precision results in increased stress concentrations where corners are covered by a layer of structural layer.

### SUMMARY OF THE INVENTION

It is an object of the present invention to provide an improved method for forming a chamber for a micro-electromechanical device.

This object is achieved in a method of forming an improved chamber for a micro-electromechanical device comprising the steps of:
a. depositing a sacrificial layer on a substrate;
b. depositing a masking layer on a surface of the sacrificial layer;
c. removing at least one predetermined portion of the masking layer down to the sacrificial layer to form an etch pattern;
d. isotropically etching the etch pattern into the sacrificial layer to a partial depth thereof and partially undercutting a remaining portion of the mask material;
e. anisotropically etching the etch pattern into the sacrificial layer to the substrate to form a recessed pattern in the sacrificial layer with at least one anchor region on the substrate surrounding at least one plateau of sacrificial layer;
f. removing the remaining masking layer;
g. depositing a structural layer over the at least one plateau and filling the recessed pattern;
h. providing an access port to the sacrificial layer; and
i. removing the remaining sacrificial layer.

It is an advantage of the present invention to eliminate the stress concentrations in microscale chambers and thereby to decrease or eliminate the chance of mechanical failure of the chamber during fabrication and operation, prolonging lifetime and robustness of the device.

### BRIEF DESCRIPTION OF THE DRAWINGS

FIG. 1a-j depicts a series of cross-sections of the preferred embodiment during various stages of the fabrication process.

FIG. 2a-j depicts a series of cross-sections of a second embodiment during various stages of the fabrication process.

FIG. 3 depicts a top view of the preferred embodiment of the device chamber.

FIG. 4 depicts a cross-sectional view along the line A-A of FIG. 3 of the preferred embodiment of the device chamber.

FIG. 5 depicts a cut-away perspective view of the preferred embodiment of the device chamber.

FIG. 6 depicts a top plan view of a third embodiment of the device chamber.

FIG. 7 depicts a top plan view of a fourth embodiment of the device chamber.

### DETAILED DESCRIPTION OF THE INVENTION

In many micro-electromechanical (MEMS) devices, a chamber is an essential component. Often, a structural layer deposited conformally over a patterned sacrificial layer forms this chamber. As will be appreciated by one skilled in the art, the planar nature of the surface micromachining processes traditionally used in MEMS manufacturing causes most standard processes to produce structures that are rectangular or trapezoidal in cross-section. If a chamber is formed over a rectangular or trapezoidal sacrificial mold, there will be a sharp corner, and therefore a stress concentration, in the chamber when the sacrificial layer is removed from beneath the chamber. As is well known to those skilled in the art, local stress is inversely proportional to the local radius of curvature, therefore a sharp corner has a small radius of curvature and a high local stress concentration. The intrinsic stress of the structural layer forming the chamber may cause it to fail mechanically at the point where the stress is concentrated, resulting in device failure due to the static forces present during device fabrication. Also, failure may occur during device use due to dynamic or external stresses, again causing failure at the point(s) where stress is most concentrated.

Elimination of these stress concentrations will decrease or eliminate the chance of mechanical failure of the chamber during fabrication, and will also prolong lifetime and robustness of the device. This is particularly important when the MEMS “system” is comprised of hundreds or thousands of devices, each of which must function for the system to be effectively utilized.

One way to eliminate this stress concentration is to form an improved chamber for a micro-electromechanical device comprising a top wall, a perimetric wall extending from the top wall to a substrate thereby forming the device chamber therebetween, and a perimetric ridge projecting from the perimetric wall into the device chamber, the perimetric wall residing adjacent to the top wall.

The preferred embodiment of the method of the current invention, comprises the steps of:
a. depositing a sacrificial layer on a substrate;
b. depositing a masking layer on a surface of the sacrificial layer;
c. depositing a photoresist on the masking layer;
d. removing at least one predetermined portion of the masking layer down to the sacrificial layer to form an etch pattern;
e. isotropically etching the etch pattern into the sacrificial layer to a partial depth thereof and partially undercutting a remaining portion of the mask material;
f. anisotropically etching the etch pattern into the sacrificial layer to the substrate to form a recessed pattern in the sacrificial layer with at least one anchor region on the substrate surrounding at least one plateau of sacrificial layer;
g. removing the remaining masking layer;
h. depositing a structural layer over the at least one plateau and filling the recessed pattern;
i. providing an access port to the sacrificial layer; and
j. removing the remaining sacrificial layer. is described in detail below.

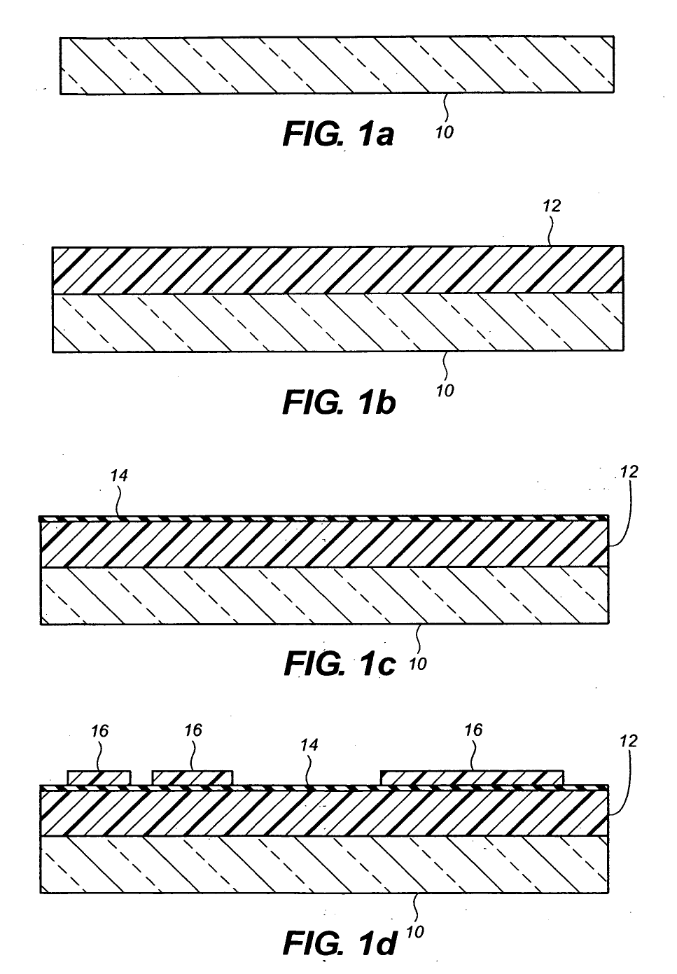

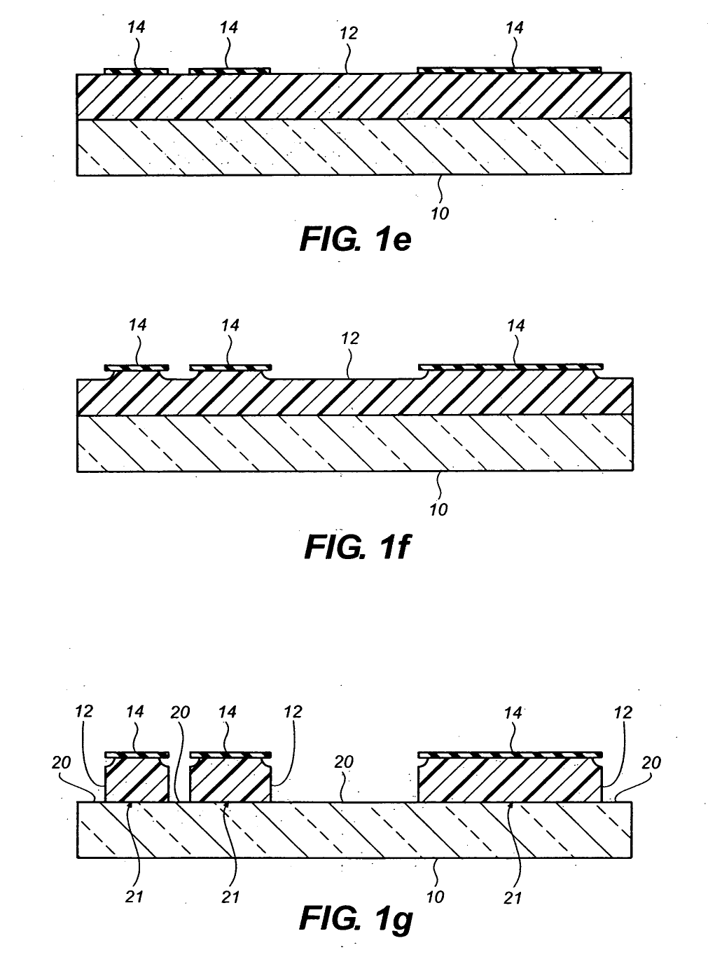

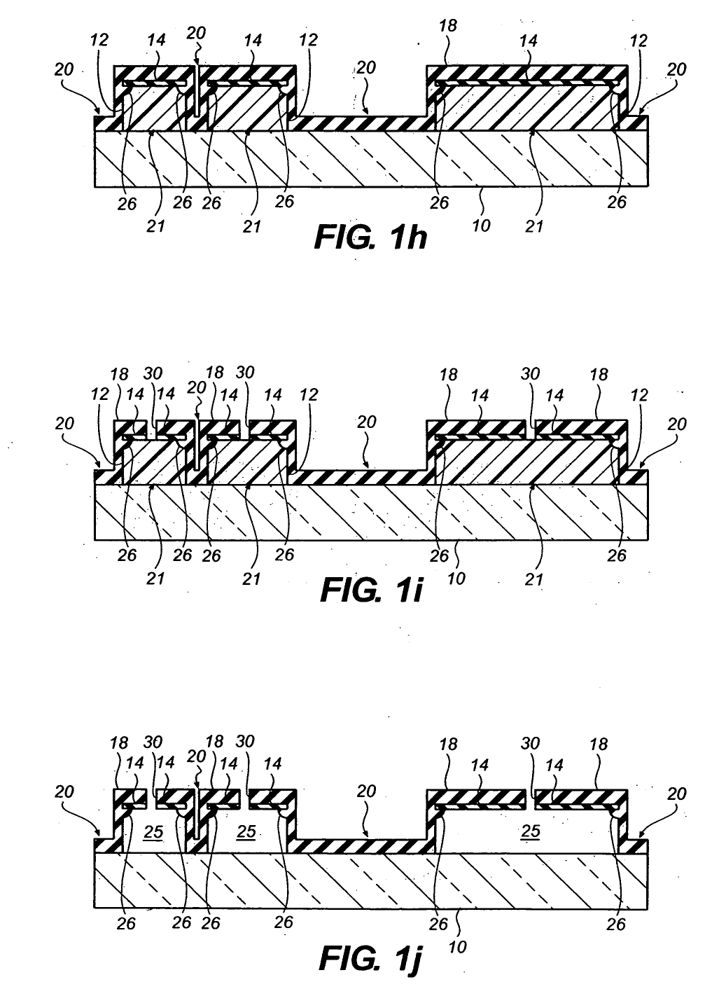

Turning now to FIG. 1a, the preferred embodiment of the process begins with a substrate 10, a rigid platform on which microscale devices are fabricated, having a nominally planar surface that may or may not have been previously processed using bulk and/or surface micromachining techniques known in the art. The substrate 10, therefore, may include CMOS devices and/or MEMS devices before the chamber fabrication process begins. A typical substrate 10 may consist of CMOS logic circuits built on a single crystal silicon wafer. The preferred embodiment uses such a substrate. Other substrate materials include, but are not limited to the following: semiconductor wafers or sheets (e.g. silicon or gallium arsenide), insulator wafers or sheets (e.g. quartz, sapphire, glass, or plastics/polymers), or metallic wafers or sheets (e.g. stainless steel or aluminum).

FIG. 1b shows a cross-section after the deposition of a sacrificial layer 12, a temporary structure that will be etched away during a future process step, onto the substrate 10. In the preferred embodiment, a polymer suspended in solvent is used as the material to form the sacrificial layer 12. This polymer is spun onto the substrate 10 using a spin coater at a particular speed to produce a certain material thickness. This method is well known to those skilled in the art. The sacrificial polymer (a polyimide) used in the preferred embodiment has the advantage of being an inexpensive process, and the polymer can form thick (1-20 um) materials quickly, as opposed to, for example plasma enhanced chemical vapor deposition, which may take minutes (e.g. TEOS-based silicon dioxide in a deposition chamber from Surface Technology Systems) to hours (e.g. silicon nitride in a deposition chamber from Surface Technology Systems) per micron of thickness of deposited material. It should be understood that it may be necessary to perform multiple spin coatings to achieve the desired thickness of sacrificial layer 12 depending on the polymer used, the viscosity of the polymer, and what the desired thickness actually is. The key characteristics of the material used to form the sacrificial layer 12 are the ability to be etched both isotropically and anisotropically, thermal tolerance to subsequent high temperature deposition processes, and a high etch rate relative to all other materials exposed during the sacrificial release process. Materials that can be used to form the sacrificial layer 12 (and their respective methods of depositions) include: polycrystalline silicon (via low-pressure chemical vapor deposition (LPCVD) or epitaxial growth or plasma-enhanced chemical vapor deposition (PECVD)) silicon dioxide (via LPCVD or PECVD, or thermal oxidation of a bare silicon substrate), or metals (via evaporation or sputtering). Use of these alternative materials will be discussed in the alternative embodiments.

Next, the sacrificial layer 12 is patterned. This can be done in several different ways, depending on the material used to form the sacrificial layer 12. In the case of the preferred embodiment, with a polyimide sacrificial layer 12, a masking layer 14 comprised of a photoresist would be removed very quickly during the polyimide etch process (both chemicals are organic and both are attacked by the same types of plasmas). In the preferred embodiment, a masking layer 14 of silicon nitride or silicon dioxide is deposited onto the sacrificial layer 12 as shown in FIG. 1c. The masking layer 14 has a high etch selectivity relative to the sacrificial layer 12. In the case of a polyimide sacrificial layer 12, silicon nitride is used as the masking layer 14 (silicon dioxide can also be used if, for instance, the nitride deposition tool was unavailable). Similarly, for a polysilicon sacrificial layer 12, silicon nitride is a common masking layer 14. If silicon dioxide is used to form the sacrificial layer 12, polysilicon can be used as a masking layer 14. However, it should be noted that direct patterning of the sacrificial layer 12 using a photoresist as the masking layer 14, is less expensive and less complicated alternative. The masking layer 14 is then patterned using a photoresist material 16 (see FIG. 1d), and the masking layer 14 is etched away in the exposed areas (see FIG. 1e). The methods used to etch these materials are well known to those skilled in the art. Since the masking layer 14 is generally relatively thin compared to the sacrificial layer 12, either an anisotropic or isotropic etch may be used. In the preferred embodiment, the silicon nitride sacrificial layer 12 is etched anisotropically in RIE (reactive ion etch) fluorine plasma.

Once the masking layer 14 has been patterned, the sacrificial layer 12 is etched to form the mold over which the structural layer 18 (see FIG. 1h) will be deposited. The sacrificial layer 12 is etched twice, first isotropically, then anisotropically. The isotropic etch results in a uniform etch in all directions. A brief isotropic etch (brief being defined as short enough that the substrate 10 is not exposed during the etch) will undercut the masking layer 14 as shown in FIG. 1f. For a truly isotropic process, the undercut region will have the profile of a quarter circle, since the sacrificial layer 12 is attacked equally in all directions. In the case of the preferred embodiment, an oxygen plasma is used to etch the polyimide material of sacrificial layer 12 isotropically. Similarly, in the case of a polysilicon sacrificial layer 12, the isotropic etch is done with a wet silicon etch in a mixture of nitric acid, water, and ammonium fluoride, or this process can be done with a gaseous xenon difluoride etch. In the case of a silicon dioxide sacrificial layer, the isotropic etch is done in hydrofluoric acid. All of these methods are well known to those skilled in the art. Since the isotropic etch is intended to be stopped after a precise amount of time, there are advantages to a plasma etch that can react only when power is supplied, rather than a gaseous or wet etchant that can continue to react until removed from the surface of the sacrificial layer 12. Therefore, the microwave oxygen plasma removal of polyimide is advantaged relative to the other methods in terms of controllable undercut dimensions.

After the brief isotropic etch described above, the sacrificial layer 12 is etched anisotropically to completion, down to the substrate 10 (see FIG. 1g). The etch must go to completion to ensure one or more anchor regions 20 where the structural layer 18 (see FIG. 1h) will make contact with the substrate 10. Without these anchor regions 20, the structural layer 18 would not be attached to the substrate 10 when the sacrificial layer 12 is removed at the end of the process. In addition, one or more plateaus 21 must be formed during the etch. The plateau(s) 21 will define the inside dimensions of the chamber 25 (see FIG. 1j). This anisotropic etch is commonly a plasma etch, such as an RIE (reactive ion etch) or ICP (inductively coupled plasma) etch to ensure the desired directionality of the etch (normal to the substrate surface). This etch would form a device with a rectangular cross-section if the undercut had not been done in the previous step.

Once the anisotropic etch of the sacrificial layer 12 has been completed, the structural layer 18 is deposited over the sacrificial mold as shown in FIG. 1h. In the preferred embodiment, the structural layer is a combination of silicon dioxide and silicon nitride, deposited by PECVD. In this embodiment, the remains of the masking layer 14 acts as a part of the chamber wall. In other embodiments, the masking layer 14 is removed before the deposition of the structural layer 18. This deposition process is conformal, and the newly deposited structural layer 18 follows the contour of the mold formed by the sacrificial layer 12. Thus, the area previously occupied by sacrificial layer 12 that was undercut during the isotropic etch of the sacrificial layer 12, is filled by the material forming structural layer 18. The structural layer 18 comprises a top wall 22 that is parallel to the surface of substrate 10, a perimetric wall 24 extending from the top wall 22 to the surface of the substrate 10 thereby forming the device chamber 25 (see FIG. 1j) therebetween, a perimetric ridge 26 projecting from the perimetric wall 24 into the device chamber 25 residing adjacent to the top wall 22; and an anchor region 20 where the structural layer 18 attaches to the substrate 10.

Once the chamber 25 (see FIG. 1j) has been formed, the sacrificial layer must be removed. First, the chamber 25 (see FIG. 1j) must be perforated with access ports 30, either through the structural layer 18, through the substrate 10, or through both the structural layer 18 and the substrate 10. In the preferred embodiment, the structural layer 18 is patterned and etched to provide access to the plateaus 21 of sacrificial layer 12 via the access ports 30. This is accomplished by using a second masking layer of photoresist (not shown). The photoresist is spun on, exposed, and developed (as is well known to those skilled in the art) to form a pattern on the structural layer 18 (see FIG. 1i). The structural layer 18 is then etched to expose the sacrificial layer 12. In the case of the preferred embodiment, the silicon nitride/silicon oxide structural layer 18 is etched using RIE fluorine plasma. The second masking layer is removed using, for example, a plasma asher or a wet resist stripper.

Finally, the sacrificial layer 12 is removed using an isotropic etch (see FIG. 1j). In the case of the preferred embodiment, oxygen plasma is used to destroy the sacrificial layer 12 via the access ports 30 without damage to the structural layer 18 or the substrate 10. Incidentally, in the preferred embodiment, the removal of the second masking layer is accomplished simultaneously with the removal of the sacrificial layer 12 due to their similar etch characteristics. This completes the chamber fabrication process.

The first alternative embodiment of the method of the current invention, comprises the steps of:
a. depositing a sacrificial layer on a substrate;
b. depositing a masking layer on a surface of the sacrificial layer;
c. removing at least one predetermined portion of the masking layer down to the sacrificial layer to form an etch pattern;
d. isotropically etching the etch pattern into the sacrificial layer to a partial depth thereof and partially undercutting a remaining portion of the mask material;
e. anisotropically etching the etch pattern into the sacrificial layer to the substrate to form a recessed pattern in the sacrificial layer with at least one anchor region on the substrate surrounding at least one plateau of sacrificial layer;
f. removing the remaining masking layer;
g. depositing a structural layer over the at least one plateau and filling the recessed pattern;
h. providing an access port to the sacrificial layer; and
i. removing the remaining sacrificial layer. is described in detail below.

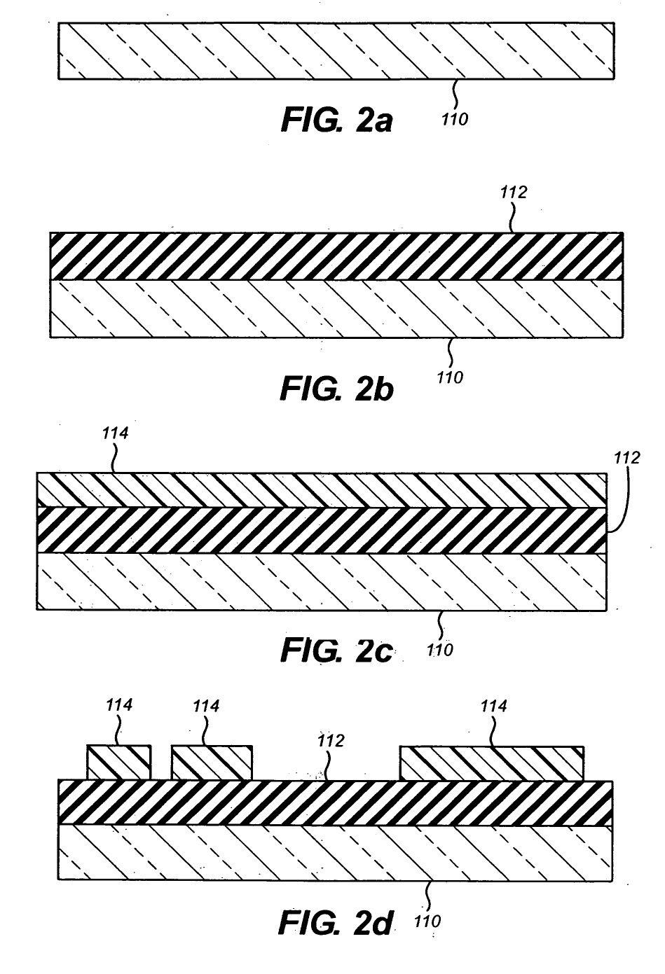

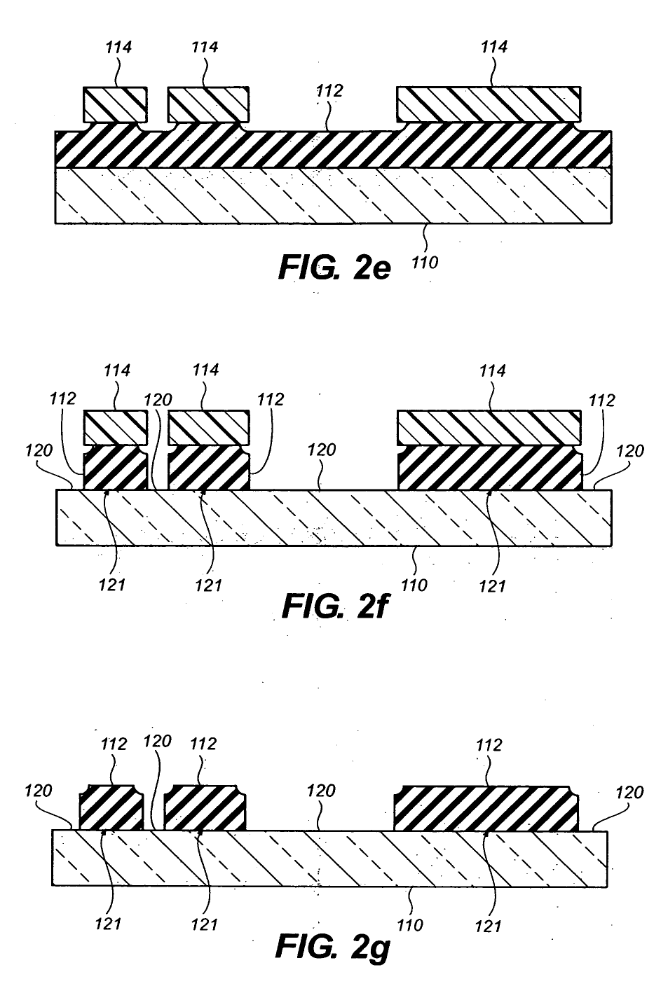

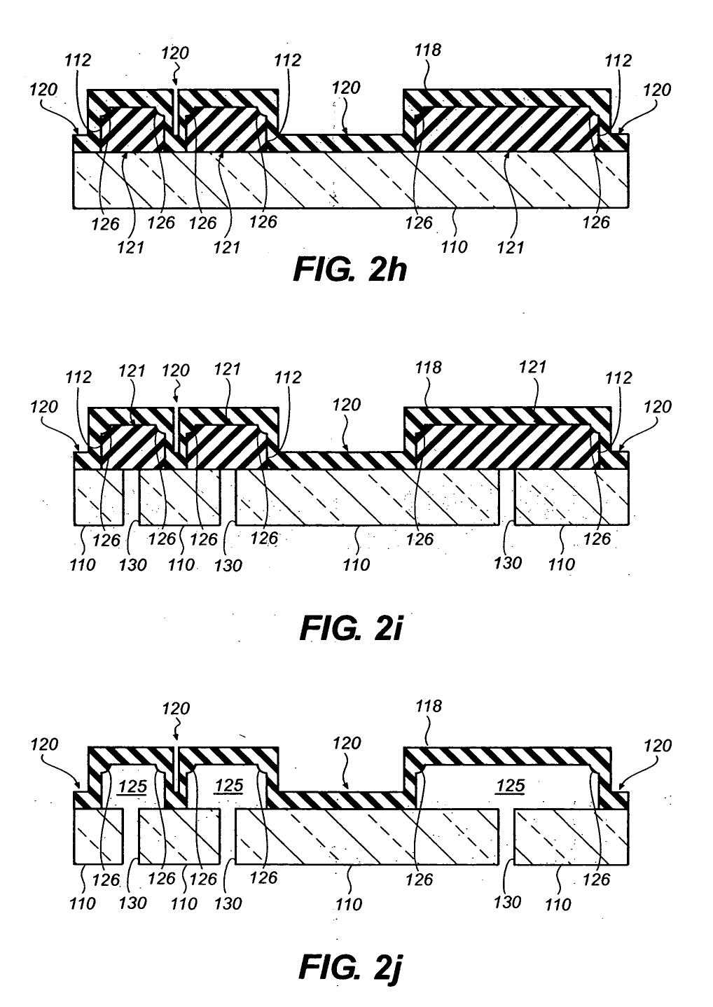

Turning now to FIG. 2a, this alternative embodiment of the process begins with a substrate 110, a rigid platform on which microscale devices are fabricated, having a nominally planar surface that may or may not have been previously processed using bulk and/or surface micromachining techniques known in the art. The substrate 110, therefore, may include CMOS devices and/or MEMS devices before the chamber fabrication process begins. A typical substrate 110 may consist of CMOS logic circuits built on a single crystal silicon wafer. The first alternative embodiment uses such a substrate. Other substrate materials include, but are not limited to the following: semiconductor wafers or sheets (e.g. silicon or gallium arsenide), insulator wafers or sheets (e.g. quartz, sapphire, glass, or plastics/polymers), or metallic wafers or sheets (e.g. stainless steel or aluminum).

FIG. 2b shows a cross-section after the deposition of a sacrificial layer 112, a temporary structure that will be etched away during a future process step, onto the substrate 110. In this alternative embodiment, silicon dioxide is used as the material to form the sacrificial layer 112. The silicon dioxide is deposited on the wafer surface by a PECVD process. This method is well known to those skilled in the art. The key characteristics of the material used to form the sacrificial layer 112 are the ability to be etched both isotropically and anisotropically, thermal tolerance to subsequent high temperature deposition processes, and a high etch rate relative to all other materials exposed during the sacrificial release process. Materials other than silicon dioxide that may be used to form sacrificial layer 112 (and their respective methods of depositions) include: polycrystalline silicon (via low-pressure chemical vapor deposition (LPCVD), or plasma-enhanced chemical vapor deposition (PECVD)), or metals (via evaporation or sputtering).

Next, the sacrificial layer 112 is patterned. In the case of the first alternative embodiment, a photoresist is deposited onto the sacrificial layer 112 as a masking layer to form layer 114 as shown in FIG. 2c. The masking layer 114 has a high etch selectivity relative to the sacrificial layer 112. For the alternative materials listed above, photoresist is used as the masking layer 114 (it should be noted that this method of direct patterning of the sacrificial layer using a photoresist as the masking layer is less expensive and less complicated than that using an inorganic masking layer for inorganic sacrificial layers, as described in the preferred embodiment). The masking layer 114 is then patterned using photolithography and the masking layer 114 is developed away in the exposed areas (see FIG. 2d). The method used to pattern this material is well known to those skilled in the art.

Once the masking layer 114 has been patterned, the sacrificial layer 112 is etched to form the mold over which the structural layer 118 will be deposited. The sacrificial layer 112 is etched twice, first isotropically, then anisotropically. The isotropic etch results in a uniform etch in all directions. A brief isotropic etch (brief being defined as short enough that the substrate 110 is not exposed during the etch) will undercut the masking layer 114 as shown in FIG. 2e. For a truly isotropic process, the undercut region will have the profile of a quarter circle, since the sacrificial layer 112 is attacked equally in all directions. In the case of this alternative embodiment, hydrofluoric acid is used to etch the silicon dioxide sacrificial layer 112 isotropically. Similarly, in the case of a polysilicon sacrificial layer 112, the isotropic etch is done with a wet silicon etch in a mixture of nitric acid, water, and ammonium fluoride, or this process can be done with a gaseous xenon difluoride etch. In the case of a sputtered metal sacrificial layer, the isotropic etch is done with the appropriate metal etchant (generally a mixture of acids). All of these methods are well known to those skilled in the art. Since the isotropic etch is intended to be stopped after a precise amount of time, there are advantages to a plasma etch that can react only when power is supplied, rather than a gaseous or wet etchant that can continue to react until removed from the surface of the sacrificial layer 112.

After the brief isotropic etch described above, the sacrificial layer 112 is etched anisotropically to completion, down to the substrate 110 (see FIG. 2f). The etch must go to completion to ensure an anchor region 120 where the material used to form structural layer 118 (to be deposited) will make contact with the substrate 110. Without this anchor region 120, the structural layer 118 would not be attached to the substrate 110 when the sacrificial layer 112 is removed at the end of the process. In addition, one or more plateaus 121 must be formed during the etch. The plateau(s) 121 will define the inside dimensions of the chamber 125 (see FIG. 2j). This anisotropic etch is commonly a plasma etch, such as an RIE (reactive ion etch) or ICP (inductively coupled plasma) etch to ensure the desired directionality of the etch (normal to the substrate surface). This etch would form a device with a rectangular cross-section if the undercut had not been done in the previous step.

Once the anisotropic etch of the sacrificial layer 112 has been completed, the masking layer 114 is removed by plasma ashing or wet stripping, as shown in FIG. 2g, before the deposition of the structural layer 118. Then the structural layer 118 is deposited over the sacrificial mold as shown in FIG. 2h. In this embodiment, the structural layer is silicon nitride, deposited by PECVD. This deposition process is conformal, and the newly deposited structural layer 118 follows the contour of the mold formed by the sacrificial layer 112. Thus, the area previously occupied by sacrificial layer 112 that was undercut during the isotropic etch of the sacrificial layer 112, is filled by the material forming structural layer 118. The structural layer 118 comprises a top wall 122 that is parallel to the surface of substrate 110, a perimetric wall 124 extending from the top wall 122 to the substrate 110 thereby forming the device chamber 125 (see FIG. 2j) therebetween, a perimetric ridge 126 projecting from the perimetric wall 124 into the device chamber 125 (see FIG. 2j) residing adjacent to the top wall 122, and an anchor region 120 where the structural layer 118 attaches to the substrate 110.

Once the chamber 125 (see FIG. 2j) has been formed, the sacrificial layer must be removed. First, the chamber 125 (see FIG. 2j) must be perforated with access ports 130, either through the structural layer 118, through the substrate 110, or through both the structural layer 118 and the substrate 110. In this alternative embodiment, the substrate 110 is patterned and etched to provide access to the plateaus 121 of sacrificial layer 112 via the access ports 130. This is accomplished by using a second masking layer of photoresist. The photoresist is spun on, exposed, and developed (as is well known to those skilled in the art) to form a pattern on the substrate 110 (see FIG. 2i). The substrate 110 is then etched to expose the sacrificial layer 112. In this alternative embodiment, the silicon substrate 110 is preferably etched using an ICP Bosch process as is well known to those skilled in the art. The second masking layer is removed using, for example, a plasma asher or a wet resist stripper.

Finally, the sacrificial layer 112 is removed using an isotropic etch (see FIG. 2j). In this alternative embodiment, hydrofluoric acid is used to destroy the sacrificial layer 112 via the access ports 130 without damage to the structural layer 118 or the substrate 110. This completes the chamber fabrication process.

An improved chamber for a micro-electromechanical device comprising:
a. a top wall;
b. a perimetric wall extending from the top wall to a substrate thereby forming the device chamber therebetween; and
c. a perimetric ridge projecting from the perimetric wall into the device chamber, the perimetric wall residing adjacent to the top wall.
is described in detail below.

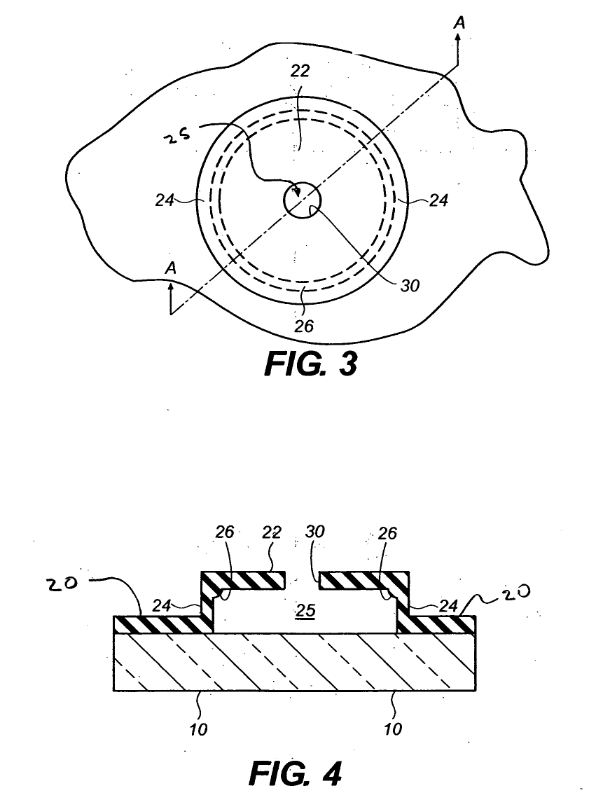

FIG. 3 shows a top plan view of the improved device chamber 25 as shown in FIG. 1j. The device chamber 25 is formed by a top wall 22 that is parallel to the surface of substrate 10, a perimetric wall 24 extending from the top wall 22 to the surface of the substrate 10, a perimetric ridge 26 projecting from the perimetric wall 24 into the device chamber 25 and residing adjacent to the top wall 22; and an anchor region 20 (see FIG. 4) attached to the substrate 10. There is an access port 30 through the top wall 22.

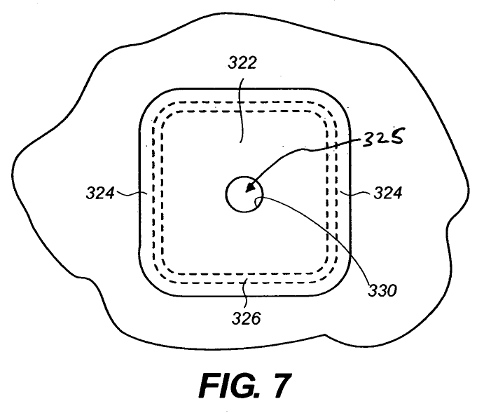

The geometry of the device chamber 25 in this case is circular, which further maximizes the local radius of curvature along the surface of the device chamber 25. Shapes other than circular can also be practiced and some specific examples will be discussed hereinafter with reference to FIG. 6 and FIG. 7. However, a circular shape is the most preferred and other continuously curved shapes such as elliptical or oval are also advantageous.

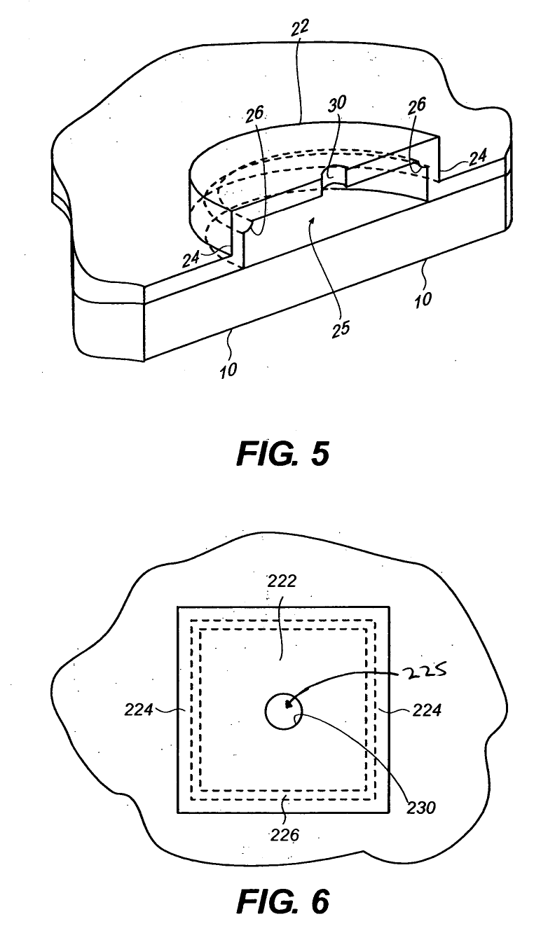

Turning next to FIGS. 4 and 5, the features of the improved device chamber 25 can be seen with more clarity. FIG. 4 shows a cross-sectional view of the device chamber 25 formed on a substrate 10 by the method of the present invention. FIG. 5 shows a perspective sectioned view of the device chamber 25. A perimetric wall 24 connects the top wall 22 to the substrate 10. Along the perimeter of the top wall 22, where the top wall 22 is adjacent to the perimetric wall 24 a perimetric ridge 26 resides adjacent to both the top wall 22 and the perimetric wall 24. This perimetric ridge 26 is rigidly attached to both the top wall 22 and the perimetric wall 24. For example, in the preferred embodiment of the method of fabrication, the structural layer 18 (as shown in FIG. 1h, i and j) comprises a top wall 22, parallel to the substrate 10 surface, a perimetric wall 24 extending from the top wall 22 to the surface of substrate 10 thereby forming the device chamber 25 therebetween. Since the structural layer is deposited uniformly over the sacrificial layer 12 (shown in FIG. 1i), the top wall 22, perimetric wall 24, and the perimetric ridge 26 are integrally formed and therefore, rigidly connected. Also shown is an access port 30 through which the material of sacrificial layer 12 was removed.

When a stress (intrinsic or external) is applied to the device chamber 25, the perimetric ridge 26 distributes the stress more evenly than the same device chamber 25 without the perimetric ridge 26. This is because the radius of curvature of the chamber surface at a sharp corner is very small (a surface with a perfectly sharp corner has a local radius of curvature of zero). In the improved device chamber 25, the radius of curvature is increased to a specified dimension by means of the inclusion of the rigidly attached material constituting the perimetric ridge 26, as shown in FIG. 4.

FIG. 6 shows a top view of a third embodiment of the improved device chamber with a square top wall 222 having an access port 230 therein, a perimetric wall 224, a perimetric ridge 226 projecting from the perimetric wall 224 into the device chamber 225 and residing adjacent to the top wall 222. However, it should be appreciated that any shape with a sharp corner would not yield all the benefits of the perimetric ridge 226, as the local radius of curvature at each of the sharp corners would be zero.

FIG. 7 shows a top plan view of a fourth embodiment of the improved device chamber. The geometry of the device chamber in this case is rectangular and similar to that shown in FIG. 6 with the exception that the corners rounded with a constant radius of curvature. This increases the minimum local radius of curvature along the surface of the device chamber 325 when compared to the local zero radius of curvature at the corners of the simple rectangular case shown in FIG. 6. Again, there is a top wall 322 having an access port 330 therein, a perimetric wall 324, a perimetric ridge 326 projecting from the perimetric wall 324 into the device chamber 325 and residing adjacent to the top wall 322.

The invention has been described in detail with particular reference to certain preferred embodiments thereof, but it will be understood that variations and modifications can be effected within the spirit and scope of the invention.

### PARTS LIST

10 Substrate
12 Sacrificial layer
14 Masking layer
16 Photoresist material
18 Structural layer
20 Anchor region
21 Plateau
22 Top wall
24 Perimetric wall
25 Device chamber
26 Perimetric ridge
30 Access port
110 Substrate
112 Sacrificial layer
114 Masking layer
116 Photoresist material
118 Structural layer
120 Anchor region
121 Plateau
122 Top wall
124 Perimetric wall
125 Chamber
126 Perimetric ridge
130 Access port
222 Top wall
224 Perimetric wall
226 Perimetric ridge
230 Access port
322 Top wall
324 Perimetric wall
325 Device chamber
326 Perimetric ridge
330 Access port

1. A method for forming an improved chamber for a micro-electromechanical device comprising the steps of:
a. depositing a sacrificial layer on a substrate;
b. depositing a masking layer on a surface of the sacrificial layer;
c. removing at least one predetermined portion of the masking layer down to the sacrificial layer to form an etch pattern;
d. isotropically etching the etch pattern into the sacrificial layer to a partial depth thereof and partially undercutting a remaining portion of the mask material;
e. anisotropically etching the etch pattern into the sacrificial layer to the substrate to form a recessed pattern in the sacrificial layer with at least one anchor region on the substrate surrounding at least one plateau of sacrificial layer;
f. removing the remaining masking layer;
g. depositing a structural layer over the at least one plateau and filling the recessed pattern;
h. providing an access port to the sacrificial layer; and
i. removing the remaining sacrificial layer.

2. A method as recited in claim 1 wherein:
the masking layer is not photosensitive.

3. A method as recited in claim 1 wherein:
the masking layer is photosensitive.

4. A method as recited in claim 2 further comprising the step of:
a. depositing a photoresist on the masking layer prior to the step of removing at least one predetermined portion of the masking layer.

5. A method as recited in claim 1 wherein:
the access port is provided through the substrate.

6. A method as recited in claim 2 wherein:
the access port is provided through the substrate.

7. A method as recited in claim 3 wherein:
the access port is provided through the substrate.

8. A method as recited in claim 4 wherein:
the access port is provided through the substrate.

9. A method as recited in claim 1 wherein:
the access port is provided through the structural layer.

10. A method as recited in claim 2 wherein:
the access port is provided through the structural layer.

11. A method as recited in claim 3 wherein:
the access port is provided through the structural layer.

12. A method as recited in claim 4 wherein:
the access port is provided through the structural layer.

13. A method as recited in claim 5 wherein:
a second access port is provided through the structural layer.

14. An improved chamber for a micro-electromechanical device comprising:
a. a top wall;
b. a perimetric wall extending from the top wall to a substrate thereby forming the device chamber therebetween; and
c. a perimetric ridge projecting from the perimetric wall into the device chamber, the perimetric wall residing adjacent to the top wall.

15. An improved chamber for a micro-electromechanical device as recited in claim 14 wherein:
the top wall is generally circular.

16. An improved chamber for a micro-electromechanical device as recited in claim 14 wherein:
the top wall is generally elliptical.

17. An improved chamber for a micro-electromechanical device as recited in claim 14 wherein:
the device chamber is generally cylindrical.

18. An improved chamber for a micro-electromechanical device as recited in claim 14 wherein:
the perimetric ridge forms a generally circular or ring-like shape.

19. A method as recited in claim 1 wherein: the device chamber is generally cylindrical.
